(19) United States
(12) Patent Application Publication
(10) Pub. No.: US 2012/0068729 A1
(43) Pub. Date: Mar. 22, 2012

(54) METHOD FOR DETERMINING THE PARAMETERS OF A PHOTOVOLTAIC DEVICE

(76) Inventors: Andreas Haslauer, Puchheim (DE); Peter Lechner, Haar (DE)

(21) Appl. No.: 13/220,846

(22) Filed: Aug. 30, 2011

(30) Foreign Application Priority Data
Aug. 31, 2010 (DE) 10 2010 035 961.0
Jan. 13, 2011 (DE) 10 2011 008 450.9

(51) Int. Cl. G01R 31/26; H01L 31/042

(52) U.S. Cl. 324/761.01; 136/244

(57) ABSTRACT

A method for determining the parameters of a photovoltaic device having at least one multi-junction solar cell is provided. The solar cell includes at least two subcells layered on top of one another and connected electrically and optically in series, each having a p-conductive layer, an intrinsic layer, and an n-conductive layer. At least one reference cell is produced for each subcell. One subcell of each reference cell corresponds to one subcell of the at least one multi-junction solar cell. In contrast, the subcell of each reference cell has at least one layer which corresponds to the i-layer of the multi-junction solar cell, but which is converted into an electrically conductive layer by doping. The spectral sensitivity of the reference cells is measured. For determining the parameters of the solar cell, the reference cells and the solar cell are measured using a solar simulator calibrated to the reference cells.

### CROSS REFERENCE TO RELATED APPLICATIONS

This application claims benefit under 35 U.S.C. §119(a) of German Patent Application No. 10 2010 035 961.0, filed Aug. 31, 2010 and German Patent Application No. 10 2010 008 450.9, filed Jan. 13, 2011, the entire contents of both which are incorporated herein by reference.

### BACKGROUND OF THE INVENTION

1. Field of the Invention

The invention relates to a method for determining the parameters of a photovoltaic device with at least one multi-junction solar cell. For carrying out the method, it also has a reference cell and/or a photovoltaic reference module as subject matter.

2. Description of Related Art

In general, thin film solar cells have the layer sequence p-i-n, i.e. a p-conductive layer or p-layer, an intrinsic layer or i-layer and an n-conductive layer or n-layer, with an electric field being produced over the entire i-layer.

In case of multi-junction solar cells comprising two, three or more subcells with the layer sequence p-i-n, which are layered on top of one another and connected electrically and optically in series, the respective i-layers may be composed of materials with the same or different band gaps. By optimizing for a specific wavelength range, efficiency is thus increased.

Within the framework of the development and for the product control of solar cells, solar simulators are used, for example xenon flash lamps, in order to measure the IV characteristic of an illuminated solar cell regarding cell efficiency or module output under standard test conditions.

Preferably, a solar simulator is used which has a radiation spectrum corresponding to the reference solar spectrum. However, even in the highest accuracy class A according to IEC 60904-9 of the solar simulator, spectral deviations up to 25% are permissible in defined wavelength ranges.

By means of calibrated reference cells, the spectral ranges of the solar simulator light can be measured and, for example, the production of solar cells thus be controlled.

For thin film solar cells and modules, crystalline solar cells filtered by colored glass are frequently used as reference cells. The purpose of the colored glass filter is to match the spectral sensitivity or quantum efficiency of the reference cell as far as possible with the quantum efficiency of the solar cell to be examined and/or the module to be examined. Since the range of appropriate colored glass filters is restricted, the matching of the spectral sensitivity of the reference cell with that of the test object succeeds only imperfectly. This causes a spectral mismatch between the test object and the reference cell, which requires an extensive adjustment of the parameters of the test object by means of a spectral mismatch factor. For this purpose, the spectral distribution of the solar reference irradiance, as indicated in IEC 60904-3, for example, the spectral irradiance distribution of the incident light during the measurement as well as the spectral sensitivity of the reference cell and the test object is required.

It is thus possible—even though with considerable effort—to examine with sufficient accuracy the parameters, in particular the performance of a single solar cell (single junction device).

The electrical measurement of a multi-junction solar cell (multi-junction device) is, however, much more difficult than that of a single solar cell, because an electrical access to the subcells is not possible and the multiple cell can thus only be measured as an electrical and optical unit via two connections.

Even though it is stated in DIN EN 60904-7 that the equation for the spectral mismatch factor can also be applied to multi-junction solar cells, such a mismatch is virtually impossible in case of multi-junction solar cells. When calibrating multi-junction solar cells, multiple light sources have to be used as solar simulators in order to take the spectral mismatch between the reference cell and the respective subcell of the multi-junction cell into account. This calibration is a time-consuming, iterative procedure, because the spectral cumulative distribution changes when the radiation intensity of a partial light source is adjusted and thus a recalculation of the mismatch factor will usually be necessary.

Alternatively, the less complex solution of a linear system of equations with n-equations—for n partial light sources being independent of one another—is possible. This requires, however, that the spectral distribution of a partial light source does not change if the intensity varies, which is only permissible in case of minor variations in a first approximation. Moreover, the small dimensions of the filtered reference solar cells of only a few square centimeters are disadvantageous. Due to local spectral and intensity inhomogeneities, large-area solar simulators can only be calibrated with such small-area reference cells by expending considerable effort in respect of measurement and time. Especially in the production of photovoltaic thin film modules, such effort is not desired.

It is thus the technical problem of the invention to provide a method as well as a reference cell and a reference module in order to precisely determine the parameters of multi-junction solar cells and photovoltaic modules with multi-junction solar cells, in particular the performance of the latter.

### BRIEF SUMMARY OF THE INVENTION

According to the invention, for determining the parameters of a photovoltaic device with at least one multi-junction solar cell comprising at least two subcells layered on top of one another and connected electrically and optically in series, each having a p-layer, an i-layer and an n-layer, a reference cell is produced for each subcell of the multi-junction solar cell according to the invention. Each reference cell comprises the same number of subcells as the multi-junction solar cell, hence at least two subcells.

One of the at least two subcells of each reference cell corresponds to one of the at least two subcells of the multi-junction solar cell, in particular in respect of the position of the reference cell, the materials and the layer thickness as well as preferably the doping, optical band gap, grading of the band gap, crystallinity, in particular Raman crystallinity, defect density and buffer layers.

This means that the one of the at least two subcells of each reference cell has the same position in the layered subcells of the reference cell as the one of the at least two subcells of the multi-junction solar cell.

In case of a double or tandem cell as a multi-junction solar cell, two reference cells are thus produced, with the bottom cell in the one reference cell corresponding to the bottom cell of the tandem cell, and the top cell in the other reference cell corresponding to the top cell of the tandem cell.

Furthermore, the one of the at least two subcells of each reference cell consists of the same materials as the one of the at least two subcells of the multi-junction solar cell, thus the same semiconducting material and the same dopants, including the dopant concentration.

In addition, the layer thicknesses of the one of the at least two subcells of each reference cell, thus the layer thickness of the p-layer, the i-layer and the n-layer, are the same as in the one subcell of the multi-junction solar cell.

Furthermore, all other features, in particular the optical band gap, grading of the band gap, crystallinity, especially Raman crystallinity, defect density and buffer layers of the one of the at least two subcells of the reference cell are preferably the same as those of the one of the at least two subcells of the multi-junction cell.

That is to say in case of a tandem cell as a multi-junction solar cell, two reference cells are produced, with the one reference cell comprising a bottom cell and the other reference cell comprising a top cell, which consists, in particular, of the same materials and has the same layer thickness as the bottom cell and/or top cell of the tandem cell, with the optical band gap, grading of the band gap, crystallinity, especially Raman crystallinity, of the bottom cell of the one reference cell and the top cell of the other reference cell preferably corresponding also identically to the bottom cell and/or top cell of the tandem cell.

In contrast, the at least one further subcell of each reference cell has at least one layer which corresponds to the i-layer of the at least one further subcell of the multi-junction solar cell, but which is converted into an electrically conductive layer by means of doping.

The further or, in case of a multi-junction solar cell with more than two subcells, each further subcell of the reference cell being converted into an electrically conductive layer by means of doping is thus photovoltaically inactive.

This means that according to the invention, for each subcell of the multi-junction solar cell a reference cell is produced, in case of which the intrinsic layer of the at least one further subcell of the multi-junction solar cell is converted into an electrically conductive layer by means of doping, wherein the p-conductive layer or the n-conductive layer or the p-conductive and the n-conductive layer of the at least one further subcell of the reference cell might not be implemented.

Hence, each reference cell comprises a first subcell having a p-i-n structure and at least one subcell being photovoltaically inactive which comprises an electrically conductive layer, but which consists of the same semiconducting material and has the same layer thickness as the at least one further subcell of the multi-junction solar cell.

Preferably, however, the at least one further subcell of the reference cell comprises the layer being converted into an electrically conductive layer by means of doping of the i-layer as well as the p-conductive layer and/or n-conductive layer of the at least one further subcell of the multi-junction solar cell, wherein especially reference cells in case of which the further subcell consists of the layer being converted into an electrically conductive layer by means of doping of the i-layer and the p-conductive layer as well as the n-conductive layer of the at least one further subcell of the multi-junction solar cell permit a particularly precise determination of the parameters of the multi-junction solar cell, in particular its performance.

That is to say that in case of a double or tandem solar cell, a reference cell is preferably produced for each of the two subcells by converting the intrinsic layer of the other subcell into an electrically conductive layer by means of doping, whereas in case of a multi-junction solar cell with more than two sublayers, a reference cell is produced for each subcell, with the intrinsic layer of the further subcells of the multi-junction solar cell is doped, i.e. converted into an electrically conductive layer.

The quantum efficiency or spectral sensitivity of the reference cells thus produced is measured by means of a solar simulator. Furthermore, the parameters of the reference cells and the parameters of the multi-junction solar cell are measured with the solar simulator under the same conditions. By comparing the parameters of the multi-junction solar cell with the parameters of the reference cells, it is possible to determine especially the performance of the multi-junction solar cell.

According to the invention, the spectral sensitivity of the reference cell to a subcell is thereby adapted largely identically to the spectral sensitivity of said subcell in the multi-junction solar cell.

The method according to the invention is particularly suited to determine the parameters of a silicon thin film multi-junction solar cell.

The p- and/or n-layer of at least one subcell of the silicon thin film multi-junction solar cell may be alloyed with carbon, oxygen and/or nitrogen in order to increase the band gap. For doping the p-layer of the subcells, boron can be used, for example, and for doping the n-layer phosphorus.

For the production of the multi-junction cells, chemical vapor deposition is preferably applied, in particular the plasma-enhanced PECVD method.

The layers of the individual subcells are produced by fractionating silicon-containing gases in the plasma. Silane or disilane usually serve as deposition gas. In addition to the (undoped) i-layers, the doped p- and n-layers are deposited, namely the p-layers through which light falls into the i-layer of the respective subcell, normally by admixture of diborane or trimethylboron to the deposition gas, and the n-layers by admixture of phosphine to the deposition gas. The i-layer of the subcells may consist of a silicon material with the same band gap, for example exclusively amorphous silicon or silicon materials with different band gaps, for example amorphous silicon in one or more subcells and microcrystalline silicon in the or the other subcells or amorphous silicon in one or more subcells and amorphous silicon germanium (Si—Ge alloy) in the or the other subcells of the multi-junction solar cell.

According to the invention, in a tandem solar cell the optical sensitivity or quantum efficiency of the bottom or top cell as a single cell is reproduced almost perfectly, which is then used as a reference cell and/or large-area reference module. The quantum efficiency of such a subcell within a tandem cell is the complex result of an optical interaction in a thin film system on non-smooth surfaces of more than ten monolayers with layer thicknesses between approximately 5 and 3000 nanometers (nm). A reproduction of the quantum efficiency with optical filters according to the prior art is thus a vain project.

According to the invention, the intrinsic and thus usually undoped layer of the other subcells of the multi-junction solar cell, i.e. the tandem solar cell in the aforementioned example, thus the intrinsic, usually undoped layer of the top cell is n- or p-doped to such an extent that the dark conductivity of the latter is at least 10E-5 S/cm, in particular at least 10E-4 S/cm. The same applies likewise to the i-layer of the bottom cell.

The method according to the invention is especially intended for the determination of the performance of a multi-junction solar cell and a photovoltaic module. As standard test conditions, an irradiance of the solar simulator of e.g. 1000 Watts per square meter (W/m²) to the layer of the multi-junction solar cell and/or of the module, a constant temperature of the solar cell of e.g. 25 degrees Celsius (° C.) and, for example, an AM1.5 G spectrum, thus the global solar radiation spectrum at an incidence angle of 48° in relation to the perpendicular are applied.

The performance results from the product of current and voltage at the maximum operation point when measuring the IV characteristic of an illuminated solar cell, i.e. by means of a solar simulator.

According to the invention, in a tandem solar cell two reference cells are thus produced, which have the same layer sequence as the tandem solar cell, but in case of which the i-layer of the top cell and/or the bottom cell is converted into an electrically conductive layer by means of doping in order to form the reference cell for the bottom cell and/or the top cell.

Subsequently, the spectral sensitivity of the two reference cells and thus the bottom and top cell is determined, which matches with the spectral sensitivity of the bottom and top cell of the tandem solar cell, the performance of which is to be determined.

The performance of the two reference cells in case of the solar reference spectrum, e.g. AM1.5 G, can be measured or calculated based on the spectral sensitivity determined. Typically, this calibration procedure is carried out at a metrology institute such as the Physikalisch-Technische Bundesanstalt (PTB) (Federal Institute of Physics and Metrology) or an accredited testing laboratory as, for example, the Fraunhofer Institute for Solar Energy Systems (ISE). For the determination of the parameters and thus the performance of the tandem solar cell to be examined, a spectrally adjustable solar simulator is used having a radiation spectrum that does not have to match with the reference solar spectrum. However, the radiation spectrum of the solar simulator is adjusted in such a manner that in a tandem cell the performance of the two reference cells matches with the performance determined during the calibration procedure.

For this purpose, mixed light from two or more light sources with different radiation frequency spectra can be generated by means of the solar simulator, wherein the mixed light may be modified additionally by filters if necessary. The solar simulator for generating mixed light can, for example, comprise xenon lamps, metal halide lamps or the like, having different radiation spectra, and may be e.g. a flashlight simulator.

For this reason, the solar simulator thus adjusted can considerably deviate from the solar reference spectrum, that is to say the solar simulator can thus match with a spectral accuracy class B or C or inferior. In addition, the radiation spectrum of the solar simulator does not have to be measured in case of the method according to the invention.

Hence, the performance of the two reference cells for the top cell and/or the bottom cell, e.g. a tandem solar cell, corresponds to the performance of the tandem solar cell in the reference solar spectrum, e.g. AM1.5 G.

The irradiance can be set to e.g. 1000 W/m² by the distance of the solar simulator and/or its performance. The performance of the tandem solar cell to be examined is measured by means of the solar simulator under the same conditions.

Thus, a performance deviation of the tandem or multi-junction solar cell to be examined from the overall performance of the reference cells may be determined with high accuracy (5% and significantly less).

According to the invention, it is possible to measure with the same accuracy the performance of a photovoltaic module comprising a plurality of single cells interconnected in series and, if necessary, forming a ready-for-use module together with contact strips, cables, back encapsulation and the like.

For this purpose, a reference module is produced for each subcell of the multi-junction solar cells of which the single cells of the module interconnected in series consist. The individual reference modules differ from each other in that in each case a different subcell of the multi-junction solar cells of the module has the layer sequence p-i-n, whereas in the other subcells of the multi-junction solar cell of the module the i-layer is converted into an electrically conductive layer and thus short-circuited.

The method according to the invention is therefore also suited for identically constructed large-area modules of any size and design.

In addition, it is perfectly suited for the application as evaluation and monitoring means for process control in the scope of process development and/or module production.

### BRIEF DESCRIPTION OF THE SEVERAL VIEWS OF THE DRAWINGS

Based on the enclosed drawings, the invention is described in more detail below by way of example.

FIGS. 1 through 3 show a schematic view of the structure of a tandem solar cell and/or a reference cell for the bottom cell and/or the top cell of the tandem solar cell;

FIG. 4 shows the spectral sensitivity of the bottom cell of the reference cell according to FIG. 2 and the bottom cell as well as the top cell of the tandem solar cell to be examined; and

FIG. 5 shows the IV characteristics and parameters of reference cells for the bottom cell according to the invention, listed in tabular form.

### DETAILED DESCRIPTION OF THE INVENTION

According to FIG. 1, the tandem solar cell comprises a transparent, electrically conductive front-electrode layer TCO, a first subcell or top cell 1, onto which light falls, a second subcell or bottom cell 2 and a back-electrode or reflector layer 3.

The top cell 1 and the bottom cell 2 are each configured as a p-i-n cell, i.e. they each have a p-layer p1, p2 on their front sides, i.e. light-incident sides, and an n-layer n1, n2 on their back sides. An intrinsic layer or i-layer i1, i2 is provided between the p-layers p1, p2 and the p-layers n1, n2 of each subcell 1, 2.

The p-layers p1, p2 and the n-layers n1, n2 each consist of amorphous silicon as well as the i-layer i1 of the top cell 1. The i-layer i2 of the bottom cell 2 consists, for example, of microcrystalline silicon. The back-electrode and reflector layer 3 is composed of several stacked metal layers Me1, Me2 and Me3, e.g. Cu (Me1), Ag (Me2) and NiV (Me3).

According to FIG. 2, for determining the parameters of the bottom cell 2 of the tandem solar cell according to FIG. 1, the reference cell Rb has the same layer sequence as the tandem solar cell according to FIG. 1, with the difference that the i-layer it of the top cell 1 is converted into an electrically conductive layer 11, that is to say short-circuited.

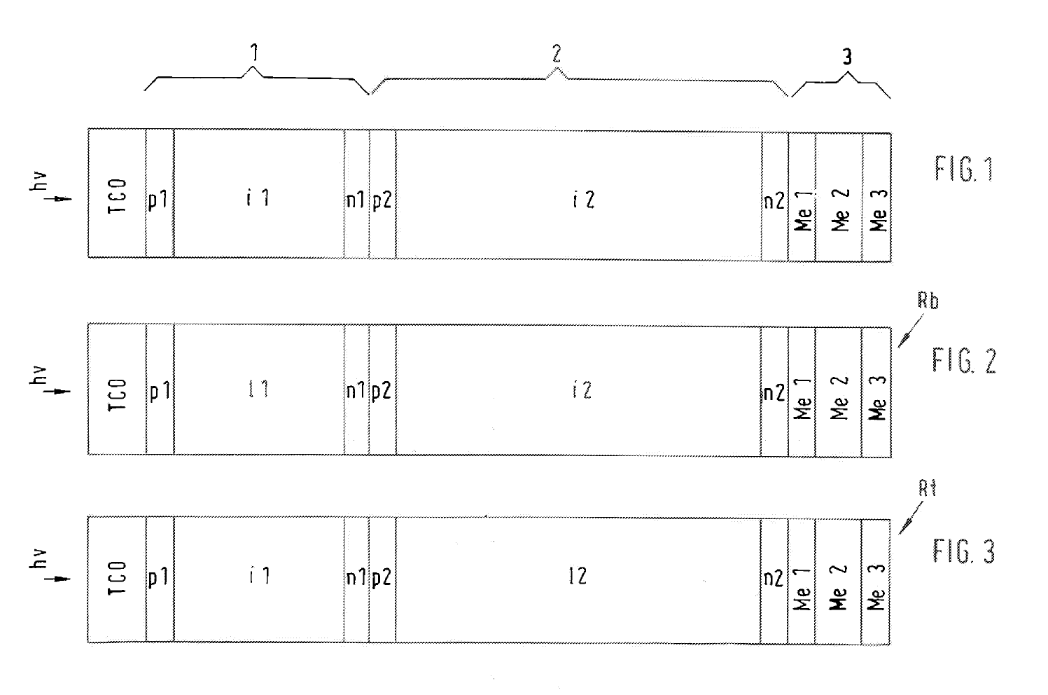

According to FIG. 3, for determining the parameters of the top cell 1 of the tandem solar cells according to FIG. 1, the reference cell Rt also has the same layer sequence as the tandem solar cell according to FIG. 1, with the difference being that the i-layer i2 of the bottom cell 2 is converted into an electrically conductive layer 12 and thus short-circuited.

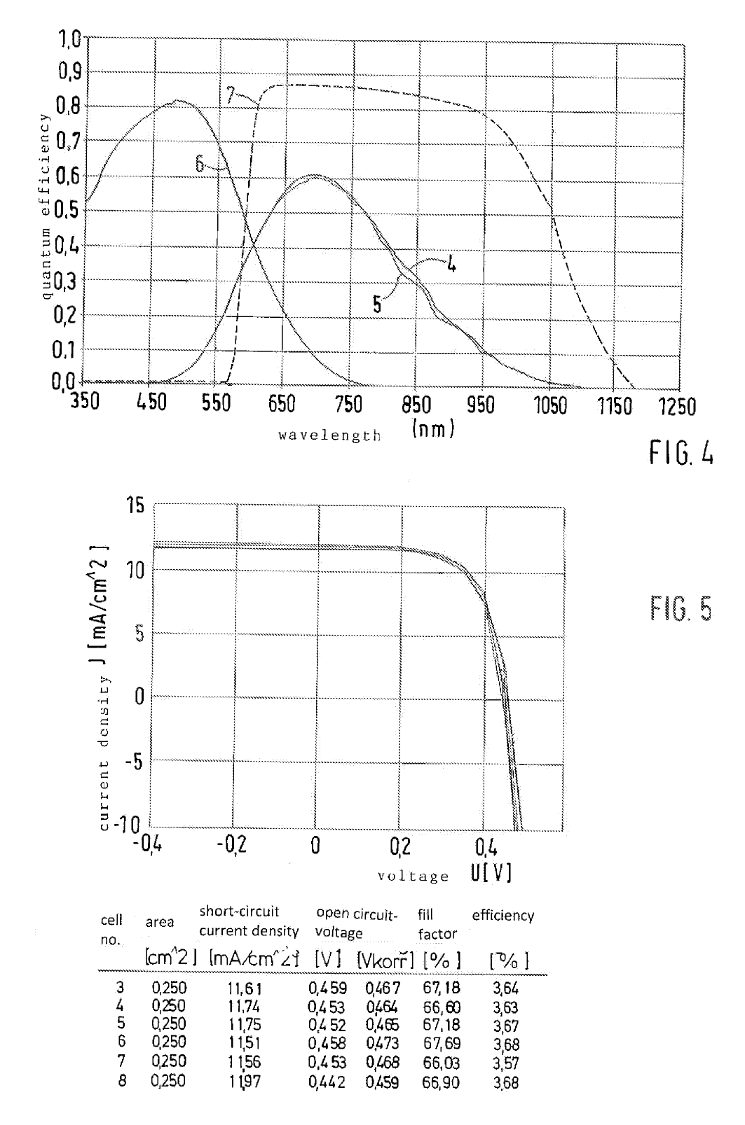

The curve 4 of FIG. 4 shows the spectral sensitivity or quantum efficiency of the bottom cell 2 of the tandem solar cell according to FIG. 1, and the curve 5 the spectral sensitivity or quantum efficiency of the bottom cell 2 of the reference cell Rb according to FIG. 2, which has the same i-layer i2 as the tandem solar cell according to FIG. 1.

It is obvious that the spectral sensitivity of the bottom cell 2 of the tandem solar cell according to FIG. 1 corresponds almost identically to the spectral sensitivity of the bottom cell 2 of the reference cell Rb.

This means if the parameters of a tandem solar cell to be examined which is configured according to FIG. 1 and the parameters of the reference cells Rb and Rt are measured by means of a solar simulator calibrated to the reference cells Rb and Rt under the same conditions, the parameters of the tandem solar cell to be examined can be determined with high accuracy and without applying a spectral mismatch factor and thus, in particular, the performance of the tandem solar cell.

The same applies likewise to the spectral sensitivity of the top cell 1 of the tandem solar cell to be examined in relation to the reference cell Rt, with the curve 6 of FIG. 4 showing the spectral sensitivity of the top cell 1 of the tandem solar cell according to FIG. 1.

In comparison, the dotted curve 7 of FIG. 4 shows the spectral sensitivity of a reference cell filtered by colored glass as used according to the prior art.

According to FIGS. 2 and 3, the reference cells Rb and Rt each have a top cell 1 and/or a bottom cell 2, in case of which the intrinsic layer of the top cell 1 and/or the bottom cell 2 has been converted into an electrically conductive and photovoltaically inactive layer 11 and/or 12, but the same p-conductive layer p1 and/or p2 and the same n-conductive layer n1 and/or n2 exists as in the tandem cell according to FIG. 1.

It is, however, also possible—without significantly affecting the precise determination of the parameters of the multi-junction solar cell, in particular its performance—to omit the p-conductive layer p1 and the n-conductive layer n1 in the top cell 1 of the reference cell Rb and the p-conductive layer p2 and the n-conductive layer n2 of the reference cell Rt in the event that the intrinsic layer has been converted into an electrically conductive layer l1 and/or l2. In this case, however, the layer l1 and/or 12 has the same layer thickness as the subcell 1 and/or 2 of the tandem cell according to FIG. 1. That is to say the overall semiconductor layer, of which the subcell 1 and/or 2 of the reference cell Rb and/or Rt consists, has been doped to an electrically conductive layer 11, 12. The conductive layer l1 and/or 12 thus has the same layer thickness as the subcell 1 and/or 2 of the tandem cell according to FIG. 1.

What is claimed is:

1. A method for determining the parameters of a photovoltaic device having at least one multi-junction solar cell which consists of at least two subcells layered on top of one another and connected electrically and optically in series, each having a p-conductive layer, an intrinsic layer and an n-conductive layer, wherein for each subcell of the at least two subcells of the at least one multi-junction solar cell of the photovoltaic device to be examined, a reference cell is produced, which comprises at least two subcells, wherein the one subcell of each reference cell corresponds to one subcell of the at least two subcells of the at least one multi-junction solar cell of the photovoltaic device to be examined, whereas the at least one further subcell of each reference cell has at least one layer which corresponds to the intrinsic layer of the at least one further subcell of the at least one multi-junction solar cell of the photovoltaic device to be examined, but which is converted into an electrically conductive layer by doping, the method comprising:
the spectral sensitivity of the reference cells is measured, and
for determining the parameters of the at least one multi-junction solar cell, the parameters of the reference cells and the parameters of the at least one multi-junction solar cell are measured by means of a solar simulator calibrated to the reference cells under the same conditions.

2. The method according to claim 1, wherein the at least one further subcell of the reference cell comprises the layer converted into an electrically conductive layer by doping of the intrinsic layer as well as the p-conductive layer and/or n-conductive layer of the at least one further subcell of the at least one multi-junction solar cell of the photovoltaic device.

3. The method according to claim 1, wherein the parameters of a silicon multi-junction solar cell are determined.

4. The method according to claim 3, wherein the intrinsic layer of the silicon multi-junction solar cell consists of silicon material with the same or different band gaps.

5. The method according to claim 1, wherein the intrinsic layer has a dark conductivity that is converted into an electrically conductive layer by doping and is at least 10E-5 S/cm.

6. The method according to claim 1, wherein the solar simulator has a radiation spectrum deviating from the reference solar spectrum.

7. The method according to claim 1, wherein the parameters required for the determination of the performance of the reference cells and the at least one multi-junction solar cell are determined.

8. The method according to claim 1, wherein the photovoltaic device consists of a photovoltaic module with a plurality of single cells.

9. A reference cell for carrying out the method according to claim 1, comprising at least two subcells, wherein the one subcell of the reference cell corresponds to one subcell of the at least two subcells of the at least one multi-junction solar cell of the photovoltaic device to be examined, whereas the at least one further subcell of each reference cell has at least one layer which corresponds to the intrinsic layer of the at least one further subcell of the at least one multi-junction solar cell of the photovoltaic device to be examined, but which is converted into an electrically conductive layer by doping.

10. The reference cell according to claim 9, wherein the at least one further subcell of the reference cell corresponds to one subcell of the at least two subcells of the at least one multi-junction solar cell of the photovoltaic device to be examined, and the at least one electrically conductive layer of the one of the at least two subcells of the reference cell corresponds to the intrinsic layer of the at least one further subcell of the one multi-junction solar cell of the photovoltaic device to be examined, but which is converted into an electrically conductive layer by doping.

11. The reference cell according to claim 9, wherein the at least one further subcell of the reference cell comprises the layer converted into an electrically conductive layer by means of doping of the intrinsic layer as well as the p-conductive layer and/or n-conductive layer of the at least one further subcell of the multi-junction solar cell.

12. A reference module for carrying out the method according to claim 8, comprising a plurality of single cells, each consisting of a multi-junction solar cell of at least two subcells layered on top of one another and connected electrically and optically in series, wherein each single cell comprises at least two subcells, wherein one of the at least two subcells has at least one electrically conductive layer.

13. A reference module for carrying out the method according to claim 8, wherein one subcell of each single cell corresponds to one subcell of the at least two subcells of the multi-junction solar cell of the photovoltaic device to be examined, whereas the at least one further subcell of the single cell has at least one layer which corresponds to the intrinsic layer of the at least one further subcell of the one multi-junction solar cell of the photovoltaic device to be examined, but which is converted into an electrically conductive layer by means of doping.

14. The reference module according to claim 13, wherein that the at least one further subcell of the single cells of the multi-junction solar cells comprises the layer converted into an electrically conductive layer by means of doping of the intrinsic layer as well as the p-conductive layer and/or n-conductive layer of the at least one further subcell of the single cells of the multi-junction solar cells.

15. A method for determining the parameters of a photovoltaic device having a top subcell, a bottom subcell, and a back electrode, the method comprising:
providing a bottom reference cell having a top subcell, a bottom subcell, and a back electrode, the bottom subcell corresponding to the bottom subcell of the photovoltaic device;
converting the top subcell of the bottom reference cell to an electrically conductive and photovoltaically inactive layer;
providing a top reference cell having a top subcell, a bottom subcell, and a back electrode, the top subcell corresponding to the top subcell of the photovoltaic device;
converting the bottom subcell of the top reference cell to an electrically conductive and photovoltaically inactive layer;
measuring parameters of the top and bottom reference cells by a solar simulator having known conditions; and
measuring the parameters of the photovoltaic device under the solar simulator with the known conditions.
